(19) United States
(12) Patent Application Publication
(10) Pub. No.: US 2025/0379099 A1
(43) Pub. Date: Dec. 11, 2025

(54) METHOD FOR FORMING A WAFER STRUCTURE AND WAFER STRUCTURE FORMED BY THE SAME

(71) Applicant: United Microelectronics Corp., Hsinchu (TW)

(72) Inventors: Zhi-Biao ZHOU, Singapore (SG); Ji Feng, Singapore (SG); Xing-Xing Chen, Singapore (SG); Wei Cheng, Singapore (SG)

(21) Appl. No.: 18/777,610

(22) Filed: Jul. 19, 2024

(30) Foreign Application Priority Data
Jun. 11, 2024 (TW) 113121450

(51) Int. Cl. H01L 21/768; H01L 21/311; H01L 27/12; H01L 29/417

(52) U.S. Cl. CPC H01L 21/76802; H01L 21/31144; H01L 21/76877; H10D 64/251; H10D 86/201

(57) ABSTRACT

A method for forming a wafer structure is provided. The method includes following steps. First, a preliminary structure is provided. The preliminary structure comprises a substrate, a buried dielectric layer, a device layer, an etch stop layer, and an interlayer dielectric layer disposed sequentially. First holes are formed through the interlayer dielectric layer at positions where contacts of a first group are to be formed. Second holes are formed through the interlayer dielectric layer, the etch stop layer, the device layer, and the buried dielectric layer at positions where contacts of a second group are to be formed. Then, the first holes are extended downward through the etch stop layer. Thereafter, the contacts of the first group are formed in the first holes, and the contacts of the second group are formed in the second holes.

This application claims the benefit of Taiwan application Serial No. 113121450, filed on Jun. 11, 2024, the subject matter of which is incorporated herein by reference.

### TECHNICAL FIELD

This disclosure relates to a method for forming a wafer structure and a wafer structure formed by the same. More particularly, the disclosure relates to a method for forming a wafer structure having different types of contacts and a wafer structure having different types of contacts formed by the same.

### BACKGROUND

Contacts are widely used for constructing electric connection paths for semiconductor devices. Typically, in a method for forming a wafer structure, a group of contacts, such as body contacts, are first fabricated. After the processes for the group of contacts are completed, another group of contacts, such as logic contacts, are fabricated. However, the conductive material for forming the first group of contacts may be undesirably left in an edge area of the wafer, and cause arcing and bias power shift in the edge area. Defects may be formed accordingly.

### SUMMARY

In this disclosure, manufacturing processes for different types of contacts are improved, so as to prevent the undesired remaining contact conductive material in the edge area of a wafer structure.

In one aspect of the disclosure, a method for forming a wafer structure is provided. The method comprises following steps. First, a preliminary structure is provided. The preliminary structure comprises a substrate, a buried dielectric layer, a device layer, an etch stop layer, and an interlayer dielectric layer. The buried dielectric layer is formed on the substrate. The device layer is formed on the buried dielectric layer. The etch stop layer is conformally formed on the device layer. The interlayer dielectric layer is formed on the etch stop layer. First holes are formed through the interlayer dielectric layer at positions where contacts of a first group are to be formed. Second holes are formed through the interlayer dielectric layer, the etch stop layer, the device layer, and the buried dielectric layer at positions where contacts of a second group are to be formed. Then, the first holes are extended downward through the etch stop layer. Thereafter, the contacts of the first group are formed in the first holes, and the contacts of the second group are formed in the second holes.

In another aspect of the disclosure, a wafer structure is provided. The wafer structure comprises a substrate, a buried dielectric layer, a device layer, an etch stop layer, an interlayer dielectric layer, contacts of a first group, and contacts of a second group. The buried dielectric layer is disposed on the substrate. The device layer is disposed on the buried dielectric layer. The etch stop layer is conformally disposed on the device layer. The interlayer dielectric layer is disposed on the etch stop layer. The contacts of the first group are disposed on the device layer through the interlayer dielectric layer and the etch stop layer. Conductive portions of the contacts of the first group directly contact the interlayer dielectric layer, the etch stop layer, and the device layer. The contacts of the second group are disposed on the substrate through the interlayer dielectric layer, the etch stop layer, the device layer, and the buried dielectric layer. Conductive portions of the contacts of the second group directly contact the interlayer dielectric layer, the etch stop layer, shallow trench isolation structures of the device layer, the buried dielectric layer, and the substrate.

### BRIEF DESCRIPTION OF THE DRAWINGS

FIGS. 1A-1H illustrate various stages of a method for forming a wafer structure according to the disclosure.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Various embodiments will be described more fully hereinafter with reference to accompanying drawings. The description and the drawings are provided for illustrative only, and not intended to result in a limitation. For clarity, the elements may not be drawn to scale. In addition, some elements and/or reference numerals may be omitted from some drawings. It is contemplated that the elements and features of one embodiment can be beneficially incorporated in another embodiment without further recitation.

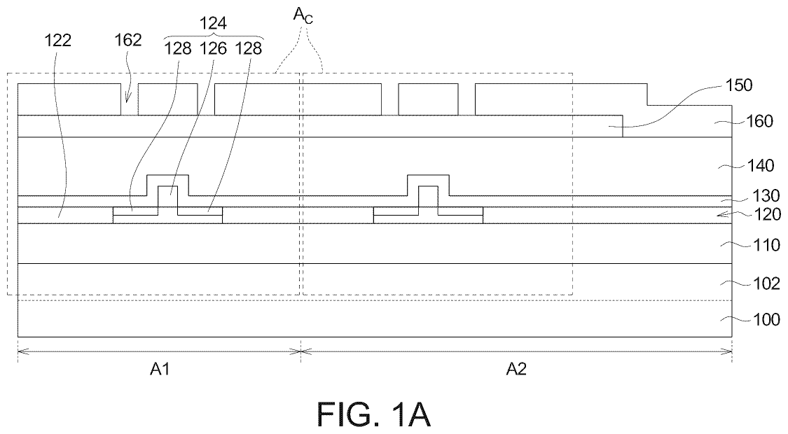

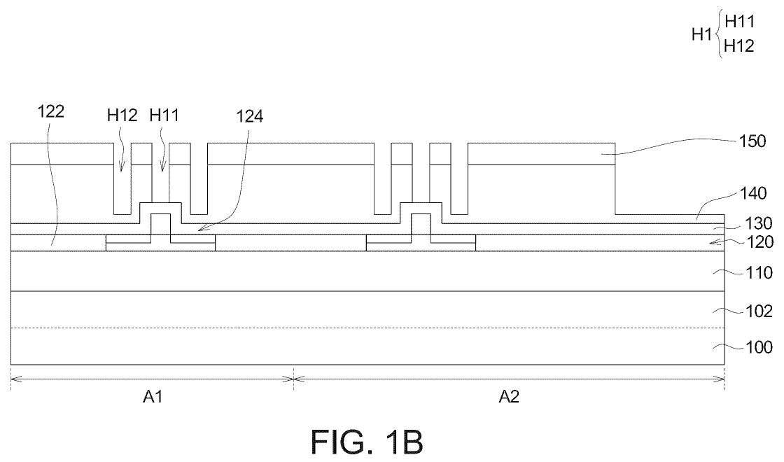

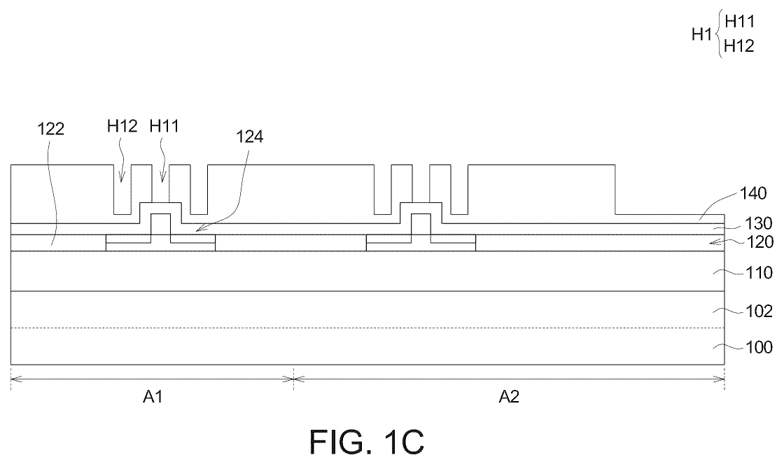

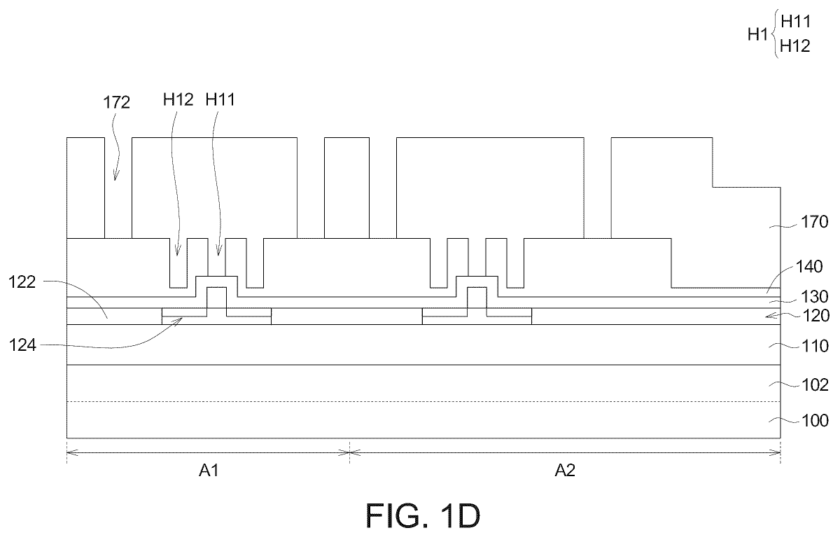

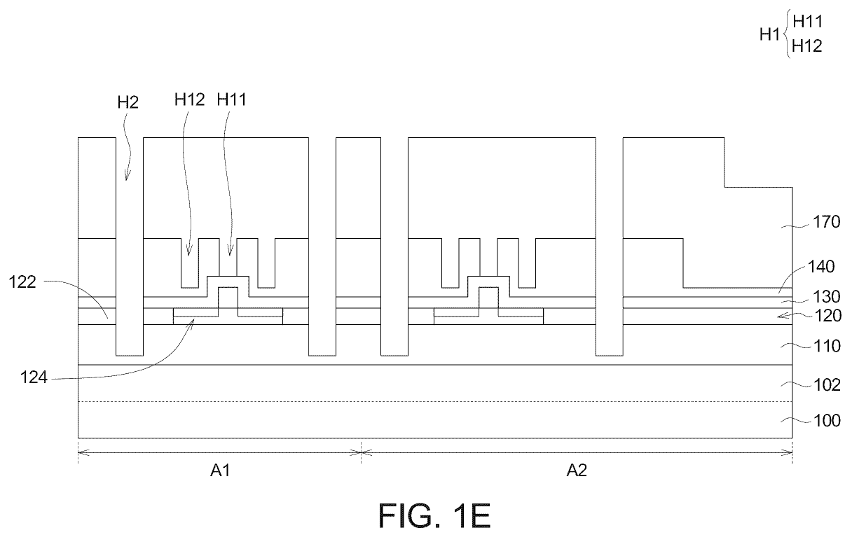

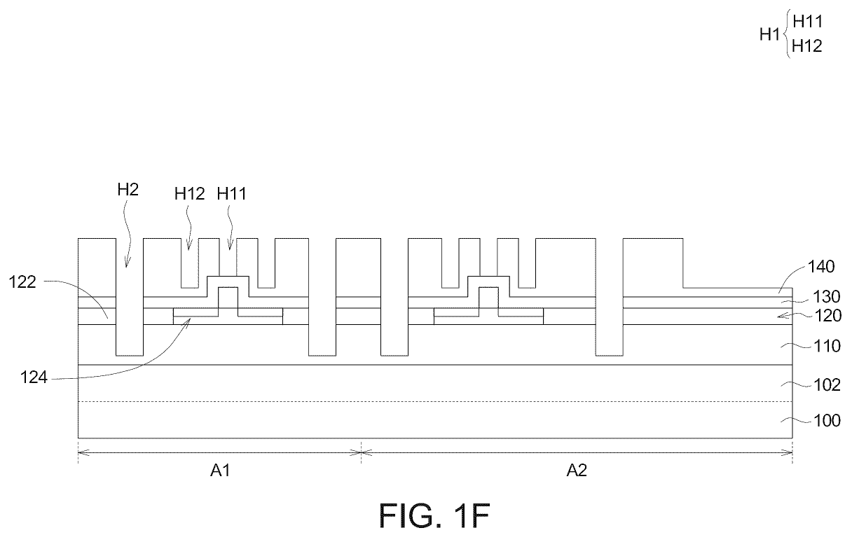

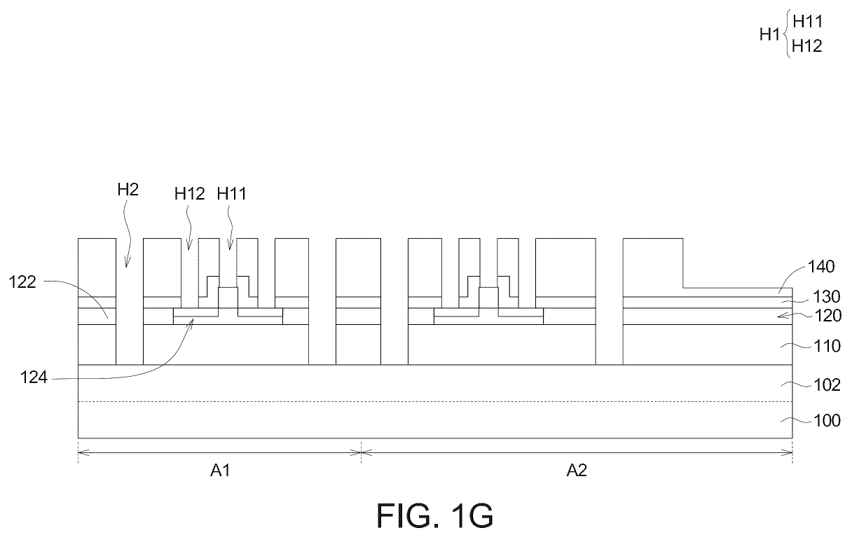

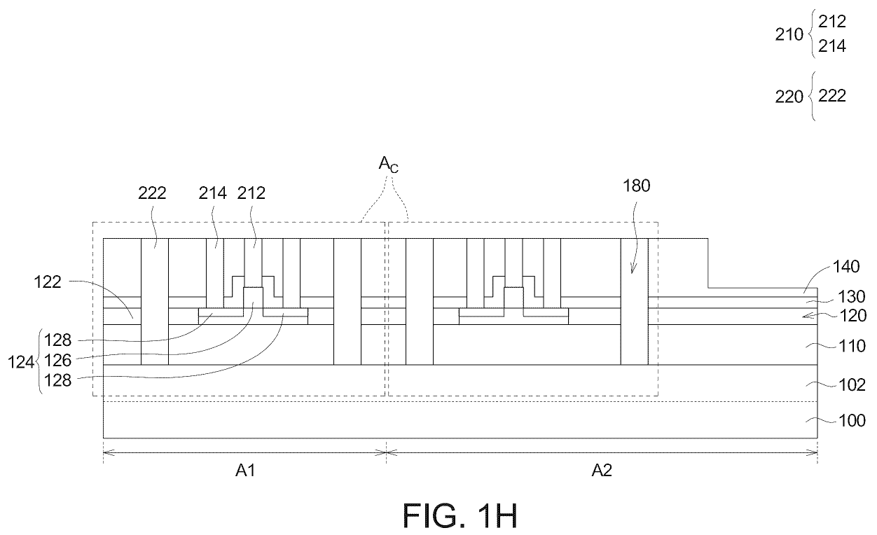

Referring to FIGS. 1A-1H, a method for forming a wafer structure according to the disclosure is shown.

As shown in FIG. 1A, a preliminary structure is provided. The preliminary structure comprises a substrate 100, a buried dielectric layer 110, a device layer 120, an etch stop layer 130, and an interlayer dielectric layer 140. The substrate 100 can be any suitable substrate in the semiconductor field, without particular limitation. According to some embodiments, the disclosure can be used in the RFSOI related field. In such conditions, the substrate 100 can comprise a trap rich layer 102. The buried dielectric layer 110 is formed on the substrate 100. The buried dielectric layer 110 can be, for example, a buried oxide layer. The device layer 120 is formed on the buried dielectric layer 110. The device layer 120 is formed, for example, by a further processing of a silicon layer. Specifically, the device layer 120 can comprise shallow trench isolation (STI) structures 122 and electronic devices such as transistors 124. A transistor 124 has a gate 126 and source/drain regions 128. The etch stop layer 130 is conformally formed on the device layer 120. The interlayer dielectric layer 140 is formed on the etch stop layer 130. The preliminary structure can further comprise a mask layer 150. The mask layer 150 is formed on the interlayer dielectric layer 140. The mask layer 150 can be formed of, for example, a photoresist, a hard mask, an advanced patterning film (APF), or a three-layer structure, but not limited thereto.

According to some embodiments, each of the preliminary structure and the subsequent wafer structures formed therefrom can have a normal area A1 and an edge area A2, and chip areas A_{c} are distributed in the normal area A1 and the edge area A2.

Then, contacts 210 of a first group and contacts 220 of a second group can be formed in the preliminary structure. The contacts 210 of the first group are, for example, logic contacts, and the contacts 220 of the second group are, for example, body contacts, but not limited thereto. The contacts 210 of the first group can comprise first contacts 212 and second contacts 214 (shown in FIG. 1H) for contacting different terminals of the electronic devices in the device layer. The contacts 220 of the second group can comprise third contacts 222 (shown in FIG. 1H). Positions where the contacts 210 of the first group are to be formed are distributed in chip areas A_{c} in the normal area A1 and the edge area A2 of the wafer structure, and positions where the contacts 220 of the second group are to be formed are distributed in the same chip areas A_{c}.

First, first holes H1 are formed through the interlayer dielectric layer 140 at the positions where the contacts 210 of the first group are to be formed. Specifically, as shown in FIG. 1A, a mask 160 is formed on the mask layer 150. The mask 160 has openings 162 at the positions where the contacts 210 of the first group are to be formed. As shown in FIG. 1B, the first holes H1 are formed through the mask layer 150 and the interlayer dielectric layer 140 using the mask 160, such as by etching. Thereafter, the mask 160 is removed. As shown in FIG. 1C, the mask layer 150 is removed.

In some embodiments, as shown in FIGS. 1B and 1C, after the step of forming the first holes H1 through the interlayer dielectric layer 140, the first holes H1 corresponding to the first contacts 212, i.e., the first holes H11 are completely through the interlayer dielectric layer 140 and expose the etch stop layer 130, and the first holes H1 corresponding to the second contacts 214, i.e., the first holes H12 are partially through the interlayer dielectric layer 140. This can be achieved by advanced process control (APC) or by simple time control. Remaining portions of the interlayer dielectric layer 140 may be beneficial in protecting the underlying device layer 120, particular the portions more sensitive to the manufacturing processes, during a subsequent step of forming openings for the contacts 220 of the second group (such as second holes H2 shown in FIGS. 1E-1G). In some alternative embodiments, after the step of forming the first holes H1 through the interlayer dielectric layer 140, all of the first holes H1, comprising the first holes H11 and the first holes H12, are completely through the interlayer dielectric layer 140 and expose the etch stop layer 130.

Then, second holes H2 are formed through the interlayer dielectric layer 140, the etch stop layer 130, the device layer 120, and the buried dielectric layer 110 at the positions where the contacts 220 of the second group are to be formed. Specifically, as shown in FIG. 1D, a mask 170 is formed on the interlayer dielectric layer 140. The mask 170 has openings 172 at the positions where the contacts 220 of the second group are to be formed. In addition, a material of the mask 170 fills into the first holes H1. The mask 170 can be, for example, a relatively thick layer formed of a photoresist, but not limited thereto. As shown in FIG. 1E, the second holes H2 are formed through the interlayer dielectric layer 140, the etch stop layer 130, the device layer 120, and the buried dielectric layer 110 using the mask 170. Thereafter, as shown in FIG. 1F, the mask 170 is removed.

Similarly, in some embodiments, as shown in FIGS. 1E and 1F, after the step of forming the second holes H2 through the interlayer dielectric layer 140, the etch stop layer 130, the device layer 120, and the buried dielectric layer 110, the second holes H2 are partially through buried dielectric layer 110. In some alternative embodiments, after the step of forming the second holes H2 through the interlayer dielectric layer 140, the etch stop layer 130, the device layer 120, and the buried dielectric layer 110, the second holes H2 are completely through the buried dielectric layer 110 and expose the substrate 100. This step can be achieved by high efficiency strip and cleaning processes. For example, alternating dry etching processes (D) and wet etching processes (W) can be used, the alternating sequence of can be DWD, WDW, or DWDW, but not limited thereto.

As shown in FIG. 1G, the first holes H1 are extended downward through the etch stop layer 130. In this step, the first holes H1 corresponding to the first contacts 212 are extended downward through the etch stop layer 130, and the first holes H1 corresponding to the second contacts 214 are extended downward through the remaining portions of the interlayer dielectric layer 140 and the etch stop layer 130. In addition, the second holes H2 can be extended downward through remaining portions of the buried dielectric layer 110. After this step, the second holes H2 are completely through the buried dielectric layer 110 and expose the substrate 100.

As shown in FIG. 1H, the contacts 210 of the first group are formed in the first holes H1, and the contacts 220 of the second group are formed in the second holes H2. Specifically, a conductive material 180 can be filled into the first holes H1 and the second holes H2, such as by deposition, and a planarization process can be conducted, so as to form the contacts 210 of the first group and the contacts 220 of the second group simultaneously. The conductive material 180 can comprise W, or the conductive material 180 can comprise Ti, TiN, and W, but not limited thereto. The conductive material filled into the first holes H1 directly contact the interlayer dielectric layer 140, the etch stop layer 130, and the device layer 120, and the conductive material filled into the second holes H2 directly contact the interlayer dielectric layer 140, the etch stop layer 130, shallow trench isolation structures of the device layer 120, the buried dielectric layer 110, and the substrate 100, without additional liners.

In some embodiments, the contacts 210 of the first group can be used as logic contacts, and comprise first contacts 212 and second contacts 214, wherein the first contacts 212 are connected to the gates 126 of the transistors 124 in the device layer 120, and the second contacts 214 are connected to the source/drain regions 128 of the transistors 124. The contacts 220 of the second group can be used as body contacts, and comprise third contacts 222. In such conditions, bottom surfaces of the first contacts 212 can have a higher level than bottom surfaces of the second contacts 214, bottom surfaces of the third contacts 222 can have a lower level than the bottom surfaces of the first contacts 212 and the bottom surfaces of the second contacts 214, and top surfaces of the first contacts 212, top surfaces of the second contacts 214, and top surfaces of the third contacts 222 can have a same level.

In the method for forming a wafer structure according to the disclosure, conductive materials are simultaneously provided to the openings for different types of contacts, so that one deposition process and one planarization process can be omitted. This is beneficial for reducing the cost. In addition, there is no previously deposited conductive material undesirably left in the edge area of the wafer structure, and thus the arc discharge and bias power shift problems in the edge area can be mitigated. Furthermore, the method for forming a wafer structure according to the disclosure adopts safe processes, such as APC, timing control, and precise logic contact fabrication without liners. Also, no high-temperature process is needed.

As shown in FIG. 1H, a wafer structure formed by the method according to the disclosure comprises a substrate 100, a buried dielectric layer 110, a device layer 120, an etch stop layer 130, an interlayer dielectric layer 140, contacts 210 of a first group, and contacts 220 of a second group. The buried dielectric layer 110 is disposed on the substrate 100. The device layer 120 is disposed on the buried dielectric layer 110. The etch stop layer 130 is conformally disposed on the device layer 120. The interlayer dielectric layer 140 is disposed on the etch stop layer 130. The contacts 210 of the first group are disposed on the device layer 120 through the interlayer dielectric layer 140 and the etch stop layer 130. Conductive portions of the contacts 210 of the first group directly contact the interlayer dielectric layer 140, the etch stop layer 130, and the device layer 120. The contacts 220 of the second group are disposed on the substrate 100 through the interlayer dielectric layer 140, the etch stop layer 130, the device layer 120, and the buried dielectric layer 110. Conductive portions of the contacts 220 of the second group directly contact the interlayer dielectric layer 140, the etch stop layer 130, shallow trench isolation structures of the device layer 120, the buried dielectric layer 110, and the substrate 100. The contacts 220 of the second group are electrically isolated from active regions of the device layer 120, such as positions where transistors 124 are disposed, by the shallow trench isolation structures 122.

Specifically, the contacts 210 of the first group can comprise first contacts 212 and second contacts 214, the contacts 220 of the second group can comprise third contacts 222, bottom surfaces of the first contacts 212 have a higher level than bottom surfaces of the second contacts 214, bottom surfaces of the third contacts 222 have a lower level than the bottom surfaces of the first contacts 212 and the bottom surfaces of the second contacts 214, and top surfaces of the first contacts 212, top surfaces of the second contacts 214, and top surfaces of the third contacts 222 have a same level. The first contacts 212 can be connected to gates 126 of the transistors 124 in the device layer 120, and the second contacts 214 can be connected to source/drain regions 128 of the transistors 124. The contacts 210 of the first group can be distributed in chip areas A_{c} in a normal area A1 and an edge area A2 of the wafer structure, and the contacts 220 of the second group can be distributed in the chip areas A_{c}. The wafer structure can have other details as described above with respect to the manufacturing processes, and such details will not be described again.

In summary, a method for forming a wafer structure and a wafer structure formed by the same are provided in the disclosure. With the improvement to the manufacturing processes for different types of contacts are improved, the undesired remaining contact conductive material in the edge area of a wafer structure and the problems caused thereby can be prevented.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A method for forming a wafer structure, comprising:
providing a preliminary structure, wherein the preliminary structure comprises:
a substrate;
a buried dielectric layer formed on the substrate;
a device layer formed on the buried dielectric layer;
an etch stop layer conformally formed on the device layer; and
an interlayer dielectric layer formed on the etch stop layer;
forming first holes through the interlayer dielectric layer at positions where contacts of a first group are to be formed;
forming second holes through the interlayer dielectric layer, the etch stop layer, the device layer, and the buried dielectric layer at positions where contacts of a second group are to be formed;
extending the first holes downward through the etch stop layer; and
forming the contacts of the first group in the first holes and forming the contacts of the second group in the second holes.

2. The method according to claim 1, wherein the positions where the contacts of the first group are to be formed are distributed in chip areas in a normal area and an edge area of the wafer structure, and the positions where the contacts of the second group are to be formed are distributed in the chip areas.

3. The method according to claim 1, wherein the preliminary structure further comprises a mask layer formed on the interlayer dielectric layer, and wherein forming the first holes through the interlayer dielectric layer comprises:
forming a mask on the mask layer, wherein the mask has openings at the positions where the contacts of the first group are to be formed;
forming the first holes through the mask layer and the interlayer dielectric layer using the mask;
removing the mask; and
removing the mask layer.

4. The method according to claim 1, wherein the contacts of the first group comprise first contacts and second contacts, and wherein after forming the first holes through the interlayer dielectric layer, the first holes corresponding to the first contacts are completely through the interlayer dielectric layer and expose the etch stop layer, and the first holes corresponding to the second contacts are partially through the interlayer dielectric layer.

5. The method according to claim 1, wherein after forming the first holes through the interlayer dielectric layer, all of the first holes are completely through the interlayer dielectric layer and expose the etch stop layer.

6. The method according to claim 1, wherein forming the second holes through the interlayer dielectric layer, the etch stop layer, the device layer, and the buried dielectric layer comprises:
forming a mask on the interlayer dielectric layer, wherein the mask has openings at the positions where the contacts of the second group are to be formed, and wherein a material of the mask fills into the first holes;
forming the second holes through the interlayer dielectric layer, the etch stop layer, the device layer, and the buried dielectric layer using the mask; and
removing the mask.

7. The method according to claim 1, wherein after forming the second holes through the interlayer dielectric layer, the etch stop layer, the device layer, and the buried dielectric layer, the second holes are partially through the buried dielectric layer, and wherein after extending the first holes downward through the etch stop layer, the second holes are completely through the buried dielectric layer and expose the substrate.

8. The method according to claim 1, wherein after forming the second holes through the interlayer dielectric layer, the etch stop layer, the device layer, and the buried dielectric layer, the second holes are completely through the buried dielectric layer and expose the substrate.

9. The method according to claim 1, wherein the contacts of the first group comprise first contacts and second contacts, and wherein at extending the first holes downward through the etch stop layer, the first holes corresponding to the first contacts are extended downward through the etch stop layer, and the first holes corresponding to the second contacts are extended downward through remaining portions of the interlayer dielectric layer and the etch stop layer.

10. The method according to claim 1, wherein forming the contacts of the first group in the first holes and forming the contacts of the second group in the second holes comprises:
filling a conductive material into the first holes and the second holes and conducting a planarization process so as to form the contacts of the first group and the contacts of the second group simultaneously.

11. The method according to claim 10, wherein the conductive material filled into the first holes directly contact the interlayer dielectric layer, the etch stop layer, and the device layer, and the conductive material filled into the second holes directly contact the interlayer dielectric layer, the etch stop layer, shallow trench isolation structures of the device layer, the buried dielectric layer, and the substrate.

12. The method according to claim 1, wherein the contacts of the first group comprise first contacts and second contacts, the contacts of the second group comprise third contacts, bottom surfaces of the first contacts have a higher level than bottom surfaces of the second contacts, bottom surfaces of the third contacts have a lower level than the bottom surfaces of the first contacts and the bottom surfaces of the second contacts, and top surfaces of the first contacts, top surfaces of the second contacts, and top surfaces of the third contacts have a same level.

13. The method according to claim 12, wherein the first contacts are connected to gates of transistors in the device layer, and the second contacts are connected to source/drain regions of the transistors.

14. A wafer structure, comprising:
a substrate;
a buried dielectric layer disposed on the substrate;
a device layer disposed on the buried dielectric layer;
an etch stop layer conformally disposed on the device layer;
an interlayer dielectric layer disposed on the etch stop layer;
contacts of a first group disposed on the device layer through the interlayer dielectric layer and the etch stop layer, wherein conductive portions of the contacts of the first group directly contact the interlayer dielectric layer, the etch stop layer, and the device layer; and
contacts of a second group disposed on the substrate through the interlayer dielectric layer, the etch stop layer, the device layer, and the buried dielectric layer, wherein conductive portions of the contacts of the second group directly contact the interlayer dielectric layer, the etch stop layer, shallow trench isolation structures of the device layer, the buried dielectric layer, and the substrate.

15. The wafer structure according to claim 14, wherein the contacts of the second group are electrically isolated from active regions of the device layer by the shallow trench isolation structures.

16. The wafer structure according to claim 14, wherein the contacts of the first group comprise first contacts and second contacts, the contacts of the second group comprise third contacts, bottom surfaces of the first contacts have a higher level than bottom surfaces of the second contacts, bottom surfaces of the third contacts have a lower level than the bottom surfaces of the first contacts and the bottom surfaces of the second contacts, and top surfaces of the first contacts, top surfaces of the second contacts, and top surfaces of the third contacts have a same level.

17. The wafer structure according to claim 14, wherein the first contacts are connected to gates of transistors in the device layer, and the second contacts are connected to source/drain regions of the transistors.

18. The wafer structure according to claim 14, wherein the contacts of the first group are distributed in chip areas in a normal area and an edge area of the wafer structure, and the contacts of the second group are distributed in the chip areas.
